(19) United States
(12) Patent Application Publication
(10) Pub. No.: US 2013/0193485 A1
(43) Pub. Date: Aug. 1, 2013

(54) COMPOUND SEMICONDUCTOR DEVICE AND METHOD OF MANUFACTURING THE SAME

(71) Applicant: FUJITSU SEMICONDUCTOR LIMITED, Yokohama-shi (JP)

(72) Inventors: Shinichi Akiyama, Aizuwakamatsu (JP); Tsutomu Hosoda, Mie (JP); Masato Miyamoto, Aizuwakamatsu (JP)

(73) Assignee: FUJITSU SEMICONDUCTOR LIMITED, Yokohama-shi (JP)

(21) Appl. No.: 13/731,759

(22) Filed: Dec. 31, 2012

(30) Foreign Application Priority Data
Jan. 27, 2012 (JP) 2012-015704

(51) Int. Cl. H01L 29/778; H01L 29/66

(52) U.S. Cl. CPC H01L 29/778; H01L 29/66431
USPC 257/194; 438/172

(57) ABSTRACT

An embodiment of a compound semiconductor device includes: an electron transit layer; an electron supply layer formed over the electron transit layer; a two-dimensional electron gas suppressing layer formed over the electron supply layer; an insulating film formed over the two-dimensional electron gas suppressing layer and the electron transit layer; and a gate electrode formed over the insulating film. The gate electrode is electrically connected with the two-dimensional electron gas suppressing layer.

### CROSS-REFERENCE TO RELATED APPLICATION

This application is based upon and claims the benefit of priority of the prior Japanese Patent Application No. 2012-015704, filed on Jan. 27, 2012, the entire contents of which are incorporated herein by reference.

### FIELD

The embodiments discussed herein are related to a compound semiconductor device and a method of manufacturing the same.

### BACKGROUND

In recent years, there has been vigorous development of high-breakdown voltage, high-output compound semiconductor devices, making use of advantages of nitride-based compound semiconductor including high saturation electron mobility and wide band gap. The development is directed to field effect transistors such as high electron mobility transistors (HEMTs), for example. Among them, a GaN-based HEMT having a GaN layer as an electron channel layer and an AlGaN layer as an electron supply layer attracts a lot of attention. In the GaN-based HEMT, lattice distortion occurs in the AlGaN layer due to difference in lattice constants between AlGaN and GaN, the distortion induces piezo polarization therealong, and thereby generates a high-density, two-dimensional electron gas, in the upper portion of the GaN layer laid under the AlGaN layer. This configuration ensures high output.

However, it is difficult to obtain normally-off transistors due to high density of the two-dimensional electron gas. Investigations into various techniques have therefore been directed to solve the problem. Conventional proposals include a technique of vanishing the two-dimensional electron gas by forming a p-type GaN layer between the gate electrode and the electron supply layer.

A GaN-based HEMT with a p-type GaN layer in which the p-type GaN layer is connected with the gate electrode, and another GaN-based HEMT with a p-type GaN layer which has MIS (metal insulator semiconductor) structure in which an insulating film is between the p-type GaN layer and the gate electrode are exemplified.

However, it is difficult to obtain a high threshold voltage in the GaN-based HEMT in which the p-type GaN layer is connected with the gate electrode. Also, it is difficult to achieve the normally-off operation properly in the GaN-based HEMT which has MIS structure.

[Patent Literature 1] Japanese Laid-Open Patent Publication No. 2008-277598

[Patent Literature 2] Japanese Laid-Open Patent Publication No. 2011-29506

[Patent Literature 3] Japanese Laid-Open Patent Publication No. 2008-103617

### SUMMARY

According to an aspect of the embodiments, a compound semiconductor device includes: an electron transit layer; an electron supply layer formed over the electron transit layer; a two-dimensional electron gas suppressing layer formed over the electron supply layer; an insulating film formed over the two-dimensional electron gas suppressing layer and the electron transit layer; and a gate electrode formed over the insulating film. The gate electrode is electrically connected with the two-dimensional electron gas suppressing layer.

According to another aspect of the embodiments, a method of manufacturing a compound semiconductor device includes: forming an electron supply layer over an electron transit layer; forming a two-dimensional electron gas suppressing layer over the electron supply layer; forming an insulating film over the two-dimensional electron gas suppressing layer and the electron transit layer; and forming a gate electrode over the insulating film. The gate electrode is electrically connected with the two-dimensional electron gas suppressing layer.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a cross sectional view illustrating a structure of a compound semiconductor device according to a first embodiment;

FIG. 2A is a view illustrating a structure of a GaN-based HEMT according to a first referential example;

FIG. 2B is a view illustrating characteristics of the first referential example;

FIG. 3 is a view illustrating characteristics of the first embodiment;

FIG. 4 is a band diagram illustrating an energy state during being OFF;

FIG. 5A is a view illustrating a structure of a GaN-based HEMT according to a second referential example;

FIG. 5B is a view illustrating characteristics of the second referential example;

FIG. 6 is a band diagram illustrating an energy state during being ON;

FIG. 7 is a view illustrating electron movement in the first embodiment;

FIGS. 8A to 8M are cross sectional views illustrating, in sequence, a method of manufacturing the compound semiconductor device according to the first embodiment;

FIG. 9 is a cross sectional view illustrating a structure of a compound semiconductor device according to a second embodiment;

FIG. 10 is a view illustrating characteristics of the second embodiment;

FIG. 11 is a view illustrating a structure of a GaN-based HEMT according to a third referential example;

FIG. 12A is a view illustrating one of characteristics of the third referential example;

FIG. 12B is a view illustrating another one of characteristics of the third referential example;

FIG. 13 is a cross sectional view illustrating a structure of a compound semiconductor device according to a third embodiment;

FIGS. 14A to 14O are cross sectional views illustrating, in sequence, a method of manufacturing the compound semiconductor device according to the third embodiment;

FIG. 15 is a cross sectional view illustrating a structure of a compound semiconductor device according to a fourth embodiment;

FIG. 16 is a drawing illustrating a discrete package according to a fifth embodiment;

FIG. 17 is a wiring diagram illustrating a power factor correction (PFC) circuit according to a sixth embodiment;

FIG. 18 is a wiring diagram illustrating a power supply apparatus according to a seventh embodiment; and

FIG. 19 is a wiring diagram illustrating a high-frequency amplifier according to an eighth embodiment.

### DESCRIPTION OF EMBODIMENTS

Embodiments will be detailed below, referring to the attached drawings.

### First Embodiment

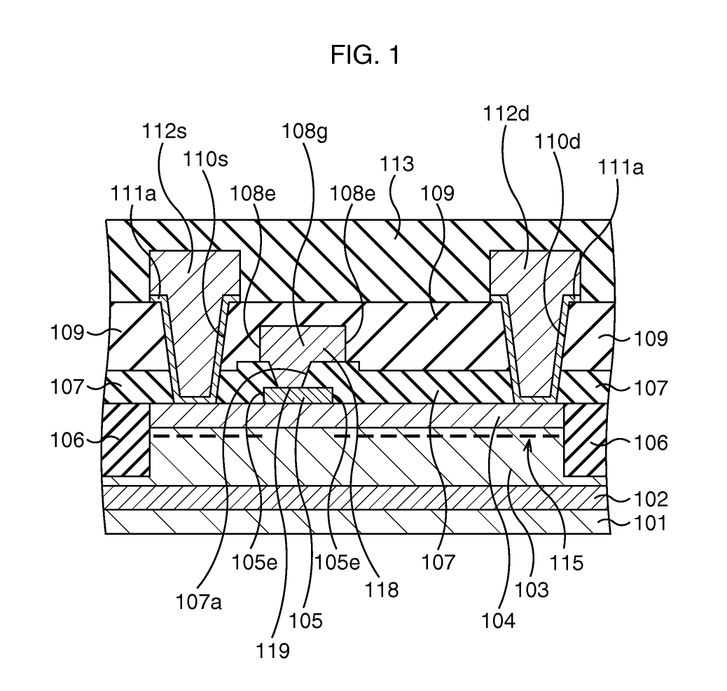

First, a first embodiment will be described. FIG. 1 is a cross sectional view illustrating a structure of a compound semiconductor device according to the first embodiment.

In the compound semiconductor device (GaN-based HEMT) according to the first embodiment, as illustrated in FIG. 1, a buffer layer 102, an electron transit layer 103 (channel layer), and an electron supply layer 104 are formed over a substrate 101. A band gap of a material of the electron supply layer 104 is wider than a band gap of a material of the electron transit layer 103. An element isolation region 106 which defines an element region is formed in the buffer layer 102, the electron transit layer 103, and the electron supply layer 104. A two-dimensional electron gas suppressing layer 105 is formed over the electron supply layer 104 in the element region. A protective film 107 which covers the two-dimensional electron gas suppressing layer 105 is formed over the electron supply layer 104 and the element isolation region 106. An opening 107a through which a part of the two-dimensional electron gas suppressing layer 105 is exposed is formed in the protective film 107. A gate electrode 108g is formed over the protective film 107. The gate electrode 108g is electrically connected with the two-dimensional electron gas suppressing layer 105 through the opening 107a. A protective film 109 which covers the gate electrode 108g is formed over the protective film 107. An opening 110s and an opening 110d are formed in the protective film 109 and the protective film 107 so that the gate electrode 108g is located between the opening 110s and the opening 110d in planar view. A source electrode 112s and a drain electrode 112d is formed in the opening 110s and the opening 110d, respectively. A conductive film 111a is formed between the inner surface of the opening 110s and the source electrode 112s, and another conductive film 111a is formed between the inner surface of the opening 110d and the drain electrode 112d. A protective film 114 which covers the source electrode 112s and the drain electrode 112d is formed over the protective film 109.

Here, details about a form of the gate electrode 108g and so on will be further described. In the present embodiment, the gate electrode 108g is formed so as to cover the whole of the two-dimensional electron gas suppressing layer 105 between the source electrode 112s and the drain electrode 112d. That is, between the source electrode and the drain electrode, end portions 108e of the gate electrode 108 overlap end portions 105e of the two-dimensional electron gas suppressing layer 105, or are located outside of the end portions 105e. Moreover, the gate electrode 108g is in contact with the two-dimensional electron gas suppressing layer 105 at a contact surface 119, and the gate electrode 108g includes at least a portion (MIS forming portion 118) located above the protective film 107 on the drain electrode 112d side of the contact surface 119.

In the first embodiment, quantum well is formed and electrons are accumulated in the quantum well, since the band gap of the electron supply layer 104 is wider than the band gap of the electron transit layer 103. As a result, a two-dimensional electron gas (2DEG 115) occurs in the vicinity of the interface with the electron supply layer 104, of the electron transit layer 103. However, the 2DEG 115 is negated beneath the two-dimensional electron gas suppressing layer 105 because of the effect of the two-dimensional electron gas suppressing layer 105. Thus, the normally-off operation may be achieved.

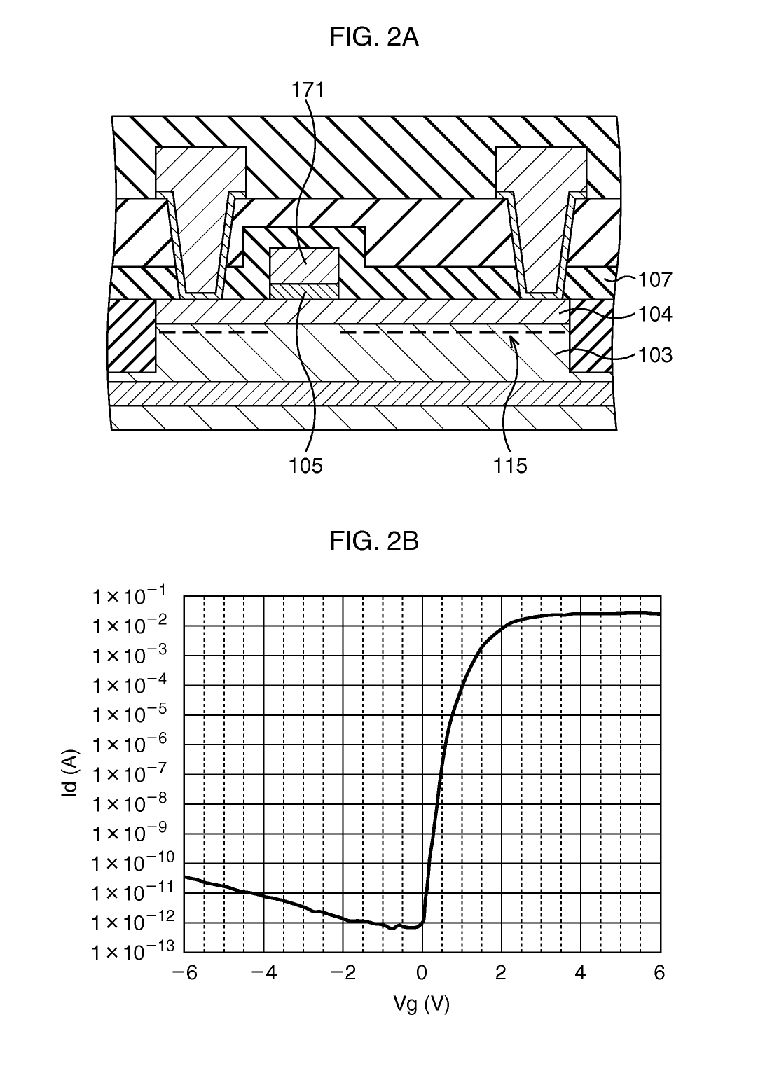

Further, a high threshold voltage may be obtained, since the gate electrode 108g includes the MIS forming portion 118 in the present embodiment. Here, the effect will be described, referring to a first referential example. FIG. 2A is a view illustrating a GaN-based HEMT of the first referential example, and FIG. 2B is a graph illustrating a relation between a gate voltage (Vg) and a drain current (Id) of the first referential example. The first referential example was manufactured by the inventors. An AlGaN layer whose Al fraction was 20% and whose thickness was 20 nm was used as the electron supply layer 104, and a p-type GaN layer doped with 4×10¹⁹ cm⁻³ of Mg whose thickness was about 80 nm was used as the two-dimensional electron gas suppressing layer 105. The result illustrated in FIG. 2B was obtained, when the Vg-Id characteristics was measured at 1V of the drain voltage. In other words, if a gate voltage (Vg) at which the drain current (Id) is 1×10⁻⁶ A is defined as a threshold voltage, the threshold voltage of the first referential example was +0.5V. The driving current was 2.7×10⁻² A.

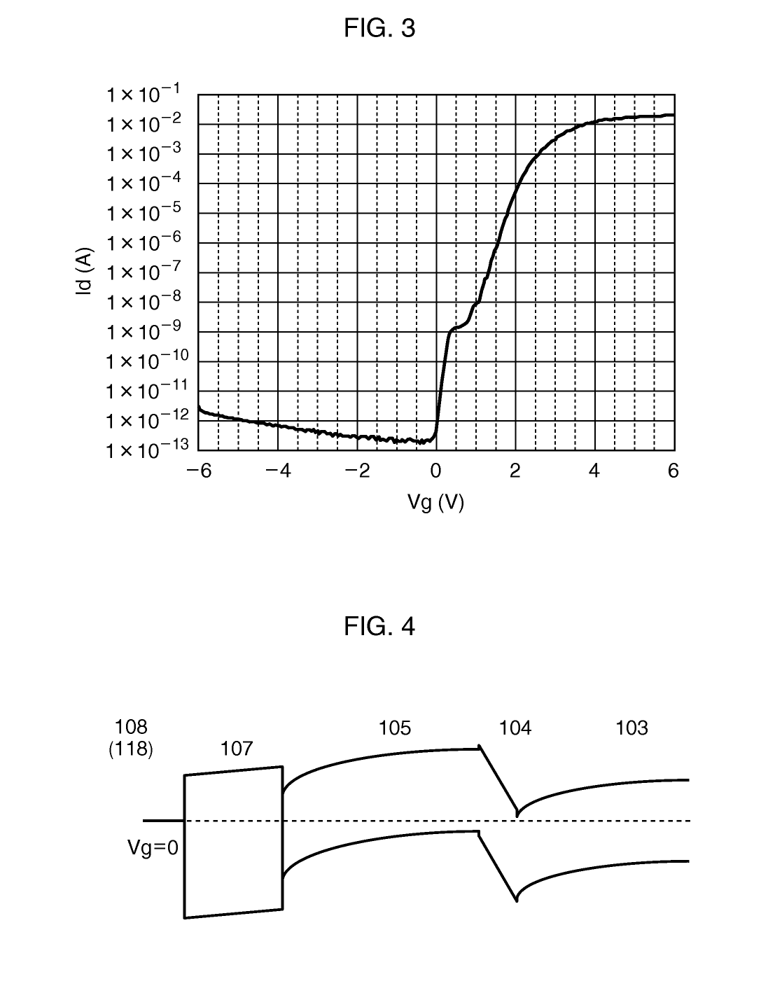

FIG. 3 is a graph illustrating a relation between a gate voltage (Vg) and a drain current (Id) of the first embodiment. The result illustrated in FIG. 3 was obtained, when the Vg-Id characteristics of a GaN-based HEMT was measured at 1V of the drain voltage, which was manufactured by the inventors following the first embodiment. Similarly to the first referential example, an AlGaN layer whose Al fraction was 20% and whose thickness was 20 nm was used as the electron supply layer 104, and a p-type GaN layer doped with 4×10¹⁹ cm⁻³ of Mg whose thickness was about 80 nm was used as the two-dimensional electron gas suppressing layer 105, for the GaN-based HEMT. If a gate voltage (Vg) at which the drain current (Id) is 1×10⁻⁶ A is defined as a threshold voltage, the threshold voltage of the first embodiment was +1.5V. In other words, extremely higher threshold voltage could be obtained than the first referential example.

The effect that such a high threshold voltage can be obtained is obvious from a depth-direction band diagram in off-state illustrated in FIG. 4, which relates to a cross section including the MIS forming portion 118. That is, the closer to the two-dimensional electron gas suppressing layer 105 from the MIS forming portion 118 (the gate electrode 108g), the higher the band of the protective film 107 is. Thus, the thicker the protective film 107 (insulating film) is, the higher threshold voltage can be obtained.

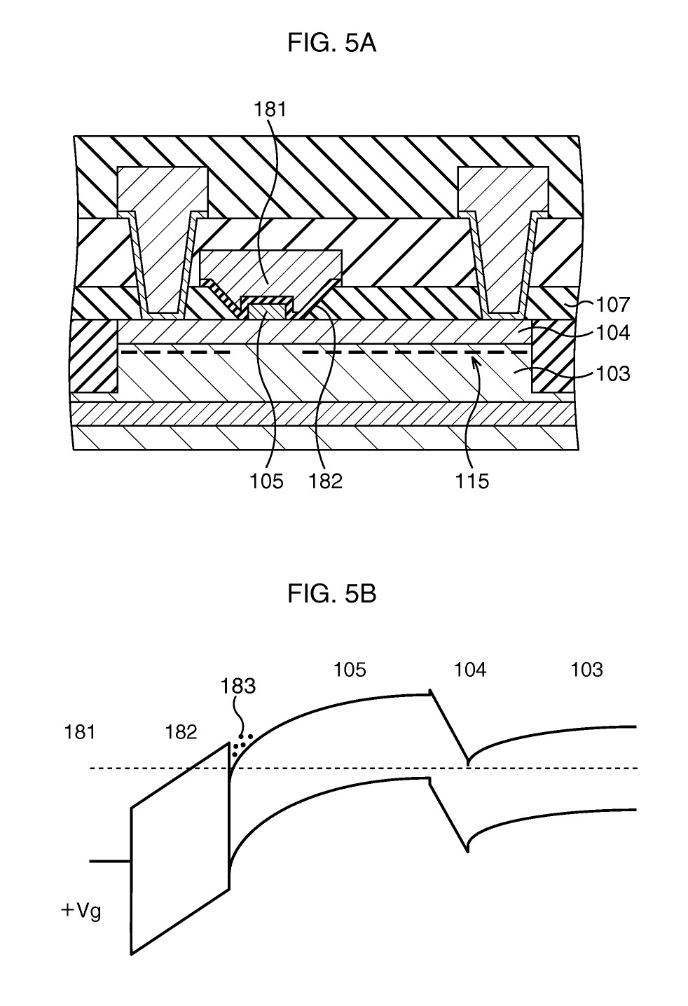

Further, the contact surface 119 is on the source electrode 112s side of the MIS forming portion 118, proper operation may be achieved in the present embodiment. Here, the effect will be described, referring to a second referential example having MIS structure. FIG. 5A is a view illustrating a GaN-based HEMT according to the second referential example, FIG. 5B is a depth-direction band diagram in on-state relating to a cross section including a gate electrode. In the second referential example, an insulating film 182 is formed so as to cover the two-dimensional electron gas suppressing layer 105, and a gate electrode 181 is formed over the insulating film 182, as illustrated in FIG. 5A. Electrons 183 are trapped in the vicinity of the interface between the insulating film 182 and the two-dimensional electron gas suppressing layer 105, even if a positive voltage is applied to the gate electrode 181 in the second referential example. Thus, an electric field does not extend to the vicinity of the interface between the electron supply layer 104 and the electron transit layer 103, and therefore 2DEG does not occur. As a result, it is difficult for the second referential example to properly operate.

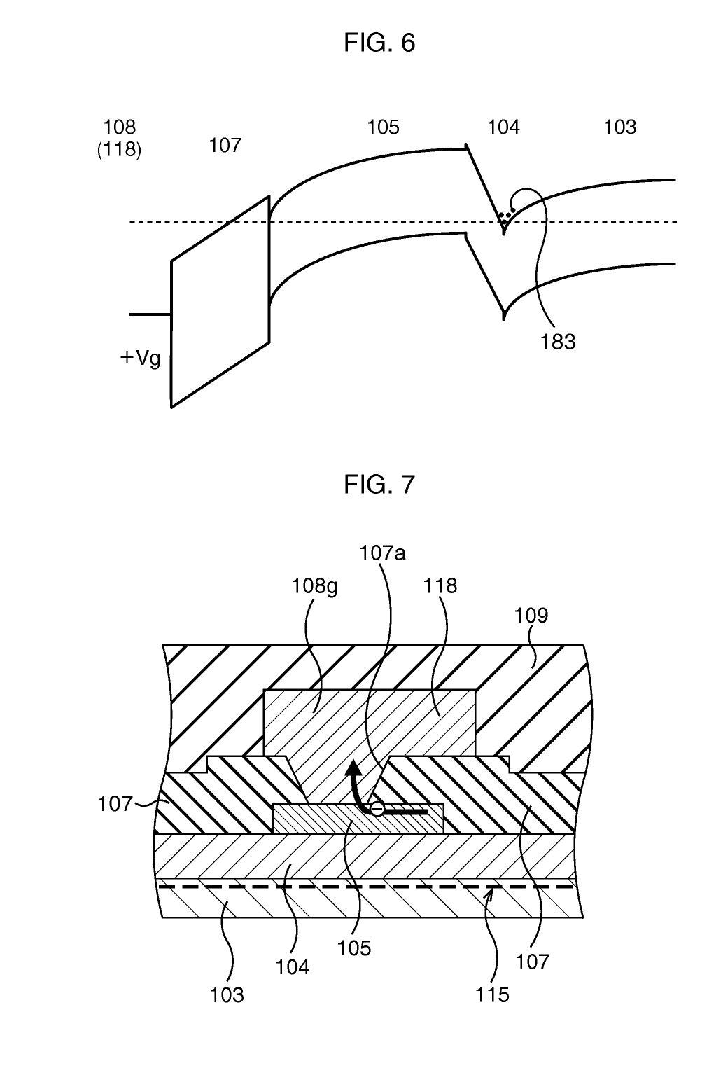

FIG. 6 is a depth-direction band diagram of the first embodiment in on-state relating to a cross section including the MIS portion 118. In contrast to the second referential example, as illustrated in FIG. 6, electrons 183 are not trapped in the vicinity of the interface between the insulating film 182 and the two-dimensional electron gas suppressing layer 105 in on-state, and therefore 2DEG occurs in the vicinity of the interface between the electron supply layer 104 and the electron transit layer 103 in the first embodiment. That is, 2DEG is obtained enough. This is because the gate electrode 108g is in contact with the two-dimensional electron gas suppressing layer 105 on the source electrode 112s side, and the electrons 183 flow into the gate electrode 108 through the contact surface 119 without being trapped, as illustrated in FIG. 7.

The result listed in Table 1 was obtained, when the Vg-Id characteristics of a GaN-based HEMT was measured at 1V of the drain voltage, which was manufactured following the second referential example. An AlGaN layer whose Al fraction was 14% and whose thickness was 18 nm was used as the electron supply layer 104, and a p-type GaN layer doped with 4×10¹⁹ cm⁻³ of Mg whose thickness was about 80 nm was used as the two-dimensional electron gas suppressing layer 105, for the GaN-based HEMT. Only a weak drain current (Id) flew as much as a leak current, and the GaN-based HEMT did not turn on. The results of the first embodiment and the first referential example are listed in Table 1, too.

TABLE 1

| | AlGaN LAYER | | p-TYPE GaN LAYER | | THRESHOLD | |
|---|---|---|---|---|---|---|
| | THICKNESS | Al FRACTION | DOSE AMOUNT OF Mg | THICKNESS | VOLTAGE | ON-CURRENT |
| | (nm) | (%) | (cm⁻³) | (nm) | (V) | (A) |
| FIRST EMBODIMENT | 20 | 20 | 4 × 10¹⁹ | ABOUT 80 | +1.5 | 2.1 × 10⁻² |
| FIRST REFERENTIAL | 20 | 20 | 4 × 10¹⁹ | ABOUT 80 | +0.5 | 2.7 × 10⁻² |
| EXAMPLE | | | | | | |
| SECOND REFERENTIAL | 18 | 14 | 4 × 10¹⁹ | ABOUT 80 | NOT TURNED ON | NOT TURNED ON |
| EXAMPLE | | | | | | |

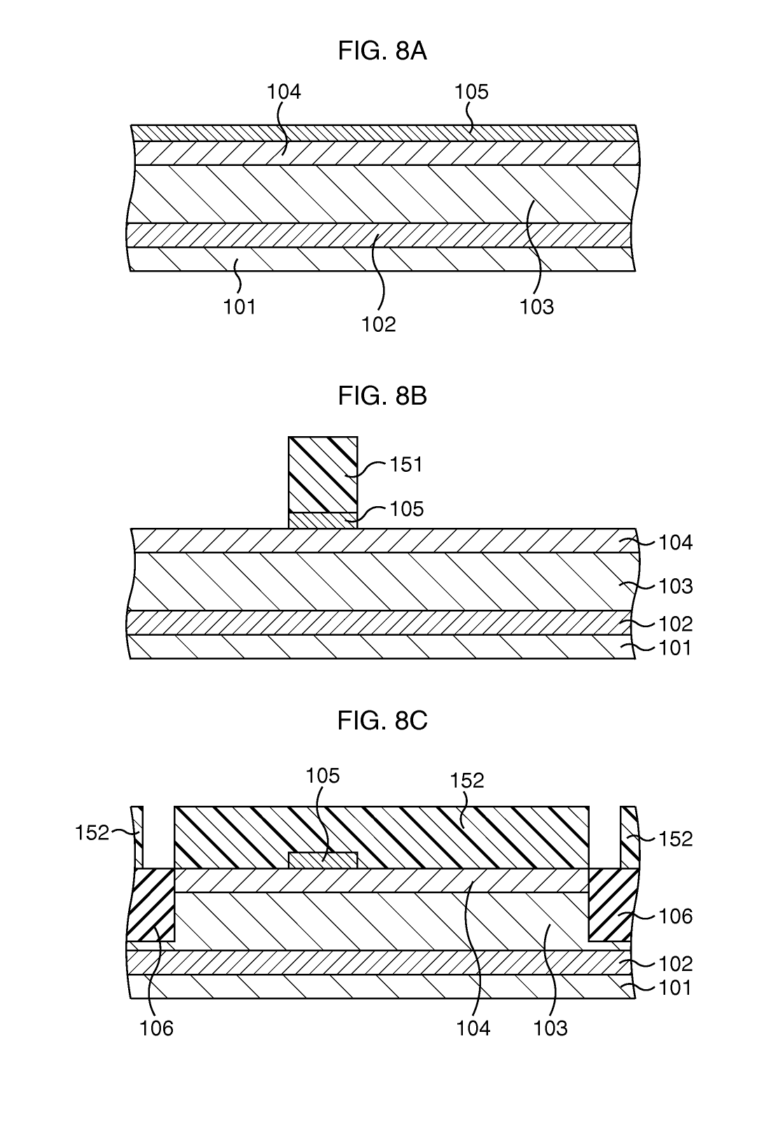

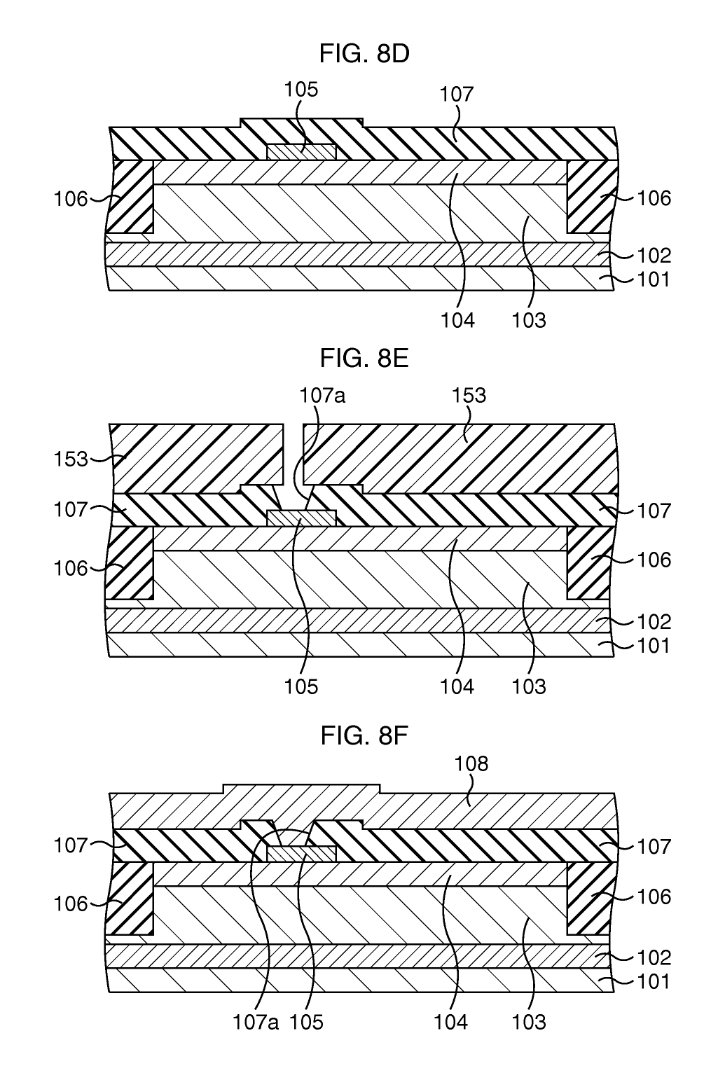

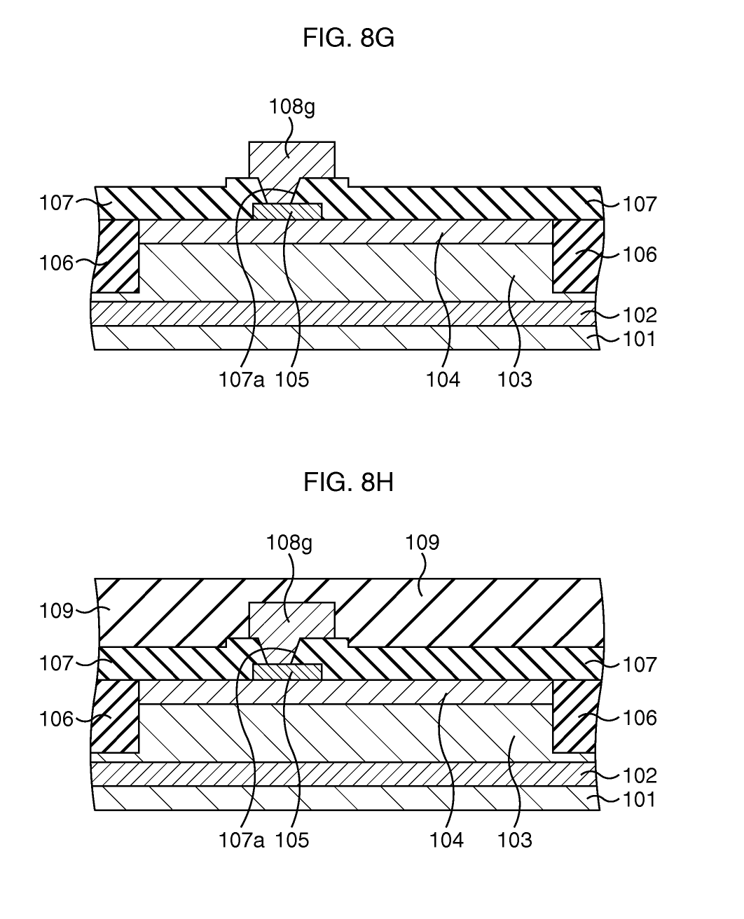

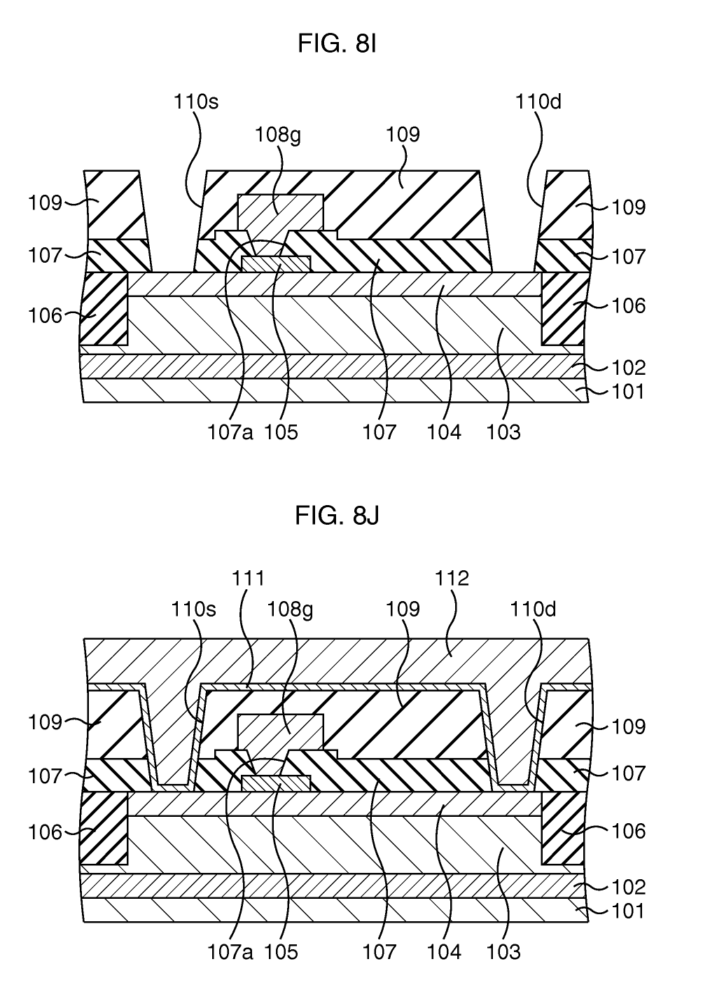

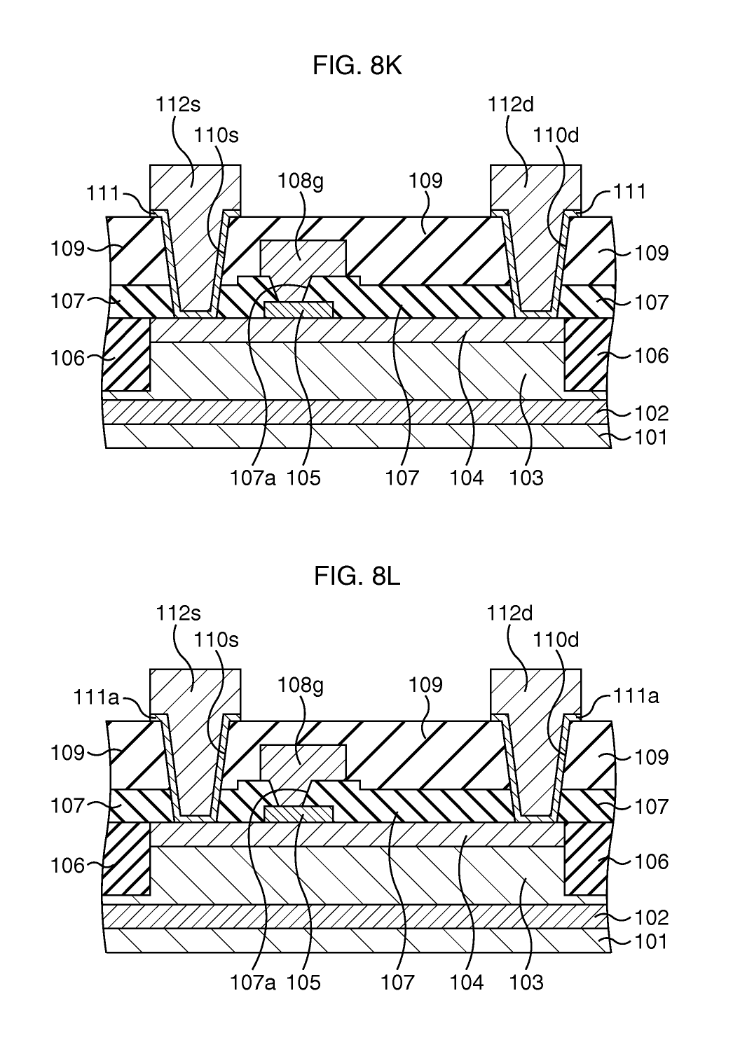

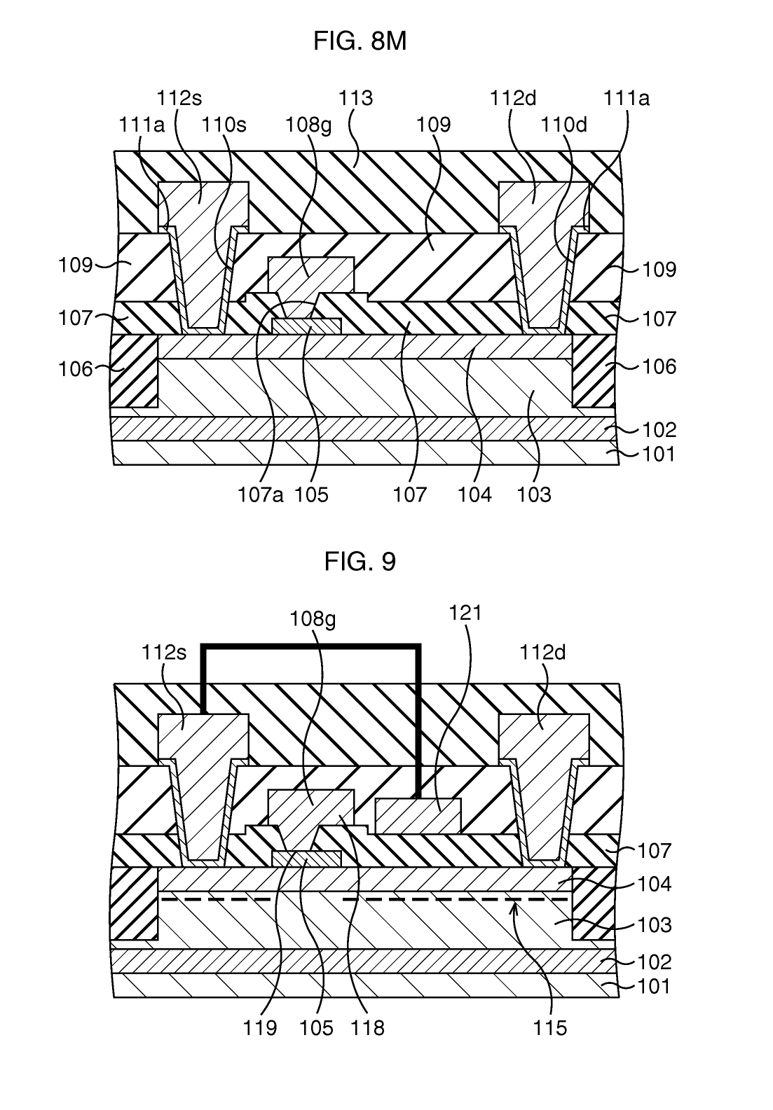

Next, a method of manufacturing the compound semiconductor device according to the first embodiment will be described. FIG. 8A to FIG. 8M are cross sectional views illustrating, in sequence, the method of manufacturing the compound semiconductor device according to the first embodiment.

First, as illustrated in FIG. 8A, the buffer layer 102 is formed over the substrate 101 such as a Si substrate. An AlN layer whose thickness is approximately 100 nm to 2 μm is formed, for example, as the buffer layer 102. A stack of alternately and repeatedly stacked AlN layers and GaN layers may be formed as the buffer layer 102, and an AlₓGa₍₁₋ₓ₎N (0<x≦1) layer whose Al fraction decreases with the increasing distance from the substrate 101 and the value x is 1 at the interface with the substrate 101 may be formed as the buffer layer 102. Thereafter, the electron transit layer (channel layer) 103 is formed over the buffer layer 102. A GaN layer whose thickness is approximately 1 μm to 3 μm is formed, for example, as the electron transit layer 103. Subsequently, the electron supply layer 104 is formed over the electron transit layer 103. An AlGaN layer whose thickness is approximately 5 nm to 40 nm is formed, for example, as the electron supply layer 104. The quantum well is formed and electrons are accumulated in the quantum well, since the band gap of AlGaN of the electron supply layer 104 is wider than the band gap of GaN of the electron transit layer 103. As a result, a two-dimensional electron gas (2DEG) occurs in the vicinity of the interface with the electron supply layer 104, of the electron transit layer 103. Then, the two-dimensional electron gas suppressing layer 105, which decreases 2DEG, is formed over the electron supply layer 104. As a result, 2DEG disappears, which occurred in the vicinity of the interface with the electron supply layer 104, of the electron transit layer 103. A p-type GaN layer whose thickness is approximately 10 nm to 300 nm is formed, for example, as the two-dimensional electron gas suppressing layer 105.

Thereafter, as illustrated in FIG. 8B, a resist pattern 151 is formed over the two-dimensional electron gas suppressing layer 105 so as to cover a region in which a gate is to be formed and expose the residual region. The two-dimensional electron gas suppressing layer 105 is etched by dry etching using the resist pattern 151 as an etching mask. As a result, 2DEG occurs in the vicinity of the interface with the electron supply layer 104, of the electron transit layer 103 again in a region where the two-dimensional electron gas suppressing layer 105 has been removed. A chlorine-containing gas or a sulfur fluoride-containing gas, for example, is used as the etching gas for the dry etching.

Subsequently, as illustrated in FIG. 8C, the resist pattern 151 is removed. Then, a resist pattern 152 is formed over the electron supply layer 104 so as to expose a region in which an element isolation region is to be formed and cover the residual region. Ion implantation using the resist pattern 152 as a mask is performed so as to damage the crystal of at least the electron supply layer 104 and the electron transit layer 103 and form the element isolation region 106, which defines the element region. Here, Ar ion or B-based ion is implanted, for example.

Thereafter, as illustrated in FIG. 8D, the resist pattern 152 is removed. Subsequently, the protective film 107 is formed over the entire surface. A silicon nitride film whose thickness is approximately 20 nm to 500 nm is formed by plasma chemical vapor deposition (CVD), for example, as the protective film 107. A silicon oxide film or a stack of a silicon nitride film and a silicon oxide film may be formed as the protective film 107. The protective film 107 may be formed by thermal CVD or atomic layer deposition (ALD).

Then, as illustrated in FIG. 8E, a resist pattern 153 is formed over the protective film 107 so as to expose a region in which a gate electrode is to be formed and cover the residual region. Wet etching is performed with chemical containing hydrofluoric acid using the resist pattern 153 as a mask. As a result, the opening 107a is formed in a region in which a gate electrode is to be formed in the protective film 107.

Thereafter, as illustrated in FIG. 8F, the resist pattern 153 is removed. Then, a conductive film 108 to be a gate electrode is formed over the entire surface. A high work function film whose thickness is approximately 10 nm to 500 nm is formed by physical vapor deposition (PVD), for example, as the conductive film 108. A film of material whose working function is 4.5 eV or higher such as Au, Ni, Co, TiN (nitrogen rich), TaN (nitrogen rich), TaC (carbon rich), Pt, W, Ru, Ni₃Si, Pd is used as the high work function film.

Then, as illustrated in FIG. 8G, the conductive film 108 is patterned so as to form the gate electrode 108g. As for patterning the conductive film 108, a resist pattern is formed over the conductive film 108 so as to cover a region in which the gate electrode 108g is to be formed and expose the residual region, dry etching is performed using the resist pattern as a mask, and the resist pattern is removed.

Thereafter, as illustrated in FIG. 8H, the protective film 109, which covers the gate electrode 108g, is formed over the protective film 107. A silicon oxide film whose thickness is approximately 100 nm to 1500 nm is formed, for example, as the protective film 109. It is preferable that the surface of the protective film 109 is flattened. If a material of the protective film 109 is applied by spin coating and then solidification by curing is performed, the flattened protective film 109 may be formed, for example. Chemical mechanical polishing (CMP) may be performed for a protective film with a concave-convex surface to form the flattened protective film 109. Moreover, these methods may be combined with each other.

Subsequently, as illustrated in FIG. 8I, the opening 110s is formed in a region in which a source electrode is to be formed, and the opening 110d is formed in a region in which a drain electrode is to be formed, in the protective film 109 and the protective film 107. As for forming the opening 110s and the opening 110d, a resist pattern is formed over the protective film 109 so as to exposes regions in which the opening 110s and the opening 110d are to be formed and cover the residual region, dry etching is performed using the resist pattern as a mask, and resist pattern is removed. The dry etching is performed, for example, with a parallel flat type etching apparatus, in an atmosphere containing CF₄, SF₆, CHF₃ or fluorine, with a substrate temperature being 25° C. to 200° C., a pressure being 10 mT to 2 Torr, and an RF power being 10 W to 400 W.

Then, as illustrated in FIG. 8J, a conductive film 111 and a conductive film 112 to be a source electrode and a drain electrode is formed over the entire surface. A low work function film such as a Ta film is formed by PVD, for example, as the conductive film 111. A film of material whose working function is lower than 4.5 eV such as Al, Ti TiN (metal rich), Ta, TaN (metal rich), Zr, TaC (metal rich), NiSi₂, Ag is used as the low work function film. The low work function film is used for the conductive film 111 in order to lower the barrier between the source electrode and drain electrode and the semiconductor beneath them, and thus lower the contact resistance. A film whose main material is Al (Al film itself) and whose thickness is approximately 20 nm to 500 nm is formed by PVD, for example, as the conductive film 112.

Thereafter, as illustrated in FIG. 8K, the conductive film 112 and the conductive film 111 are patterned so as to form the source electrode 112s and the drain electrode 112d. As for patterning the conductive film 112 and the conductive film 111, a resist pattern is formed over the conductive film 112 so as to cover a region in which the source electrode 112s and the drain electrode 112d are to be formed and expose the residual region, dry etching is performed using the resist pattern as a mask, and the resist pattern is removed. At this time, an upper part of the protective film 109 may be etched by over-etching.

Subsequently, as illustrated in FIG. 8L, an annealing treatment is performed thereby to change the conductive film 111 to a conductive film 111a with a lower contact resistance. For example, an atmosphere of this annealing treatment is an atmosphere of one or more kinds of noble gas, nitrogen, oxygen, ammonia, and hydrogen, a time is equal to or less than 180 seconds, and a temperature is 550° C. to 650° C. By the annealing treatment, the conductive film 111 and Al in the conductive film 112 react with each other, generating a small amount of Al spikes to a semiconductor part (electron supply layer 104). As a result, a contact resistance is reduced. On this occasion, the low work function of Al also contributes to lowering of the resistance.

Then, as illustrated in FIG. 8M, a protective film 113 is formed over the entire surface. A silicon oxide film whose thickness is approximately 100 nm to 1500 nm is formed, for example, as the protective film 113. It is preferable that the surface of the protective film 113 is flattened. If a material of the protective film 113 is applied by spin coating and then solidification by curing is performed, the flattened protective film 113 may be formed, for example. Chemical mechanical polishing (CMP) may be performed for a protective film with a concave-convex surface to form the flattened protective film 113. Moreover, these methods may be combined with each other.

Thereafter, an opening exposing the gate electrode 108g is formed in the protective film 113 and the protective film 109, and an opening exposing the source electrode 112s and an opening exposing the drain electrode 112d are formed in the protective film 113. A wiring for a gate, a wiring for a source, and a wiring for a drain are formed in these openings, respectively. These openings may be formed, for example, by etching using a resist pattern as a mask. These wirings may be formed, for example, by forming a metal film, patterning the metal film and so on.

Note that, when 2DEG is allowed to occur again, the two-dimensional electron gas suppressing layer 105 may be just thinned without being removed in the residual region other than the region in which the gate is to be formed in planar view. In this case, a thickness of the two-dimensional electron gas suppressing layer 105 after thinning is preferably 10 nm or less. The reason is because 2DEG occurs sufficiently.

### Second Embodiment

Next, a second embodiment will be described. FIG. 9 is a cross sectional view illustrating a structure of a compound semiconductor device according to the second embodiment.

In the compound semiconductor device (GaN-based HEMT) according to the second embodiment, as illustrated in FIG. 9, a field plate 121 is formed over the protective film 107 in a region between the gate electrode 108g and the drain electrode 112d in planar view. The field plate 121 is electrically connected with the source electrode 112s. That is, the field plate 121 is provided with the same potential as the source electrode 112s. Other structure is similar to the first embodiment.

Electric field concentration may be eased between the gate electrode 108g and the drain electrode 112d by the electric field spreading from the field plate 121 in the second embodiment.

### Third Embodiment

Next, a third embodiment will be described. In the third embodiment, electric field concentration may be further eased.

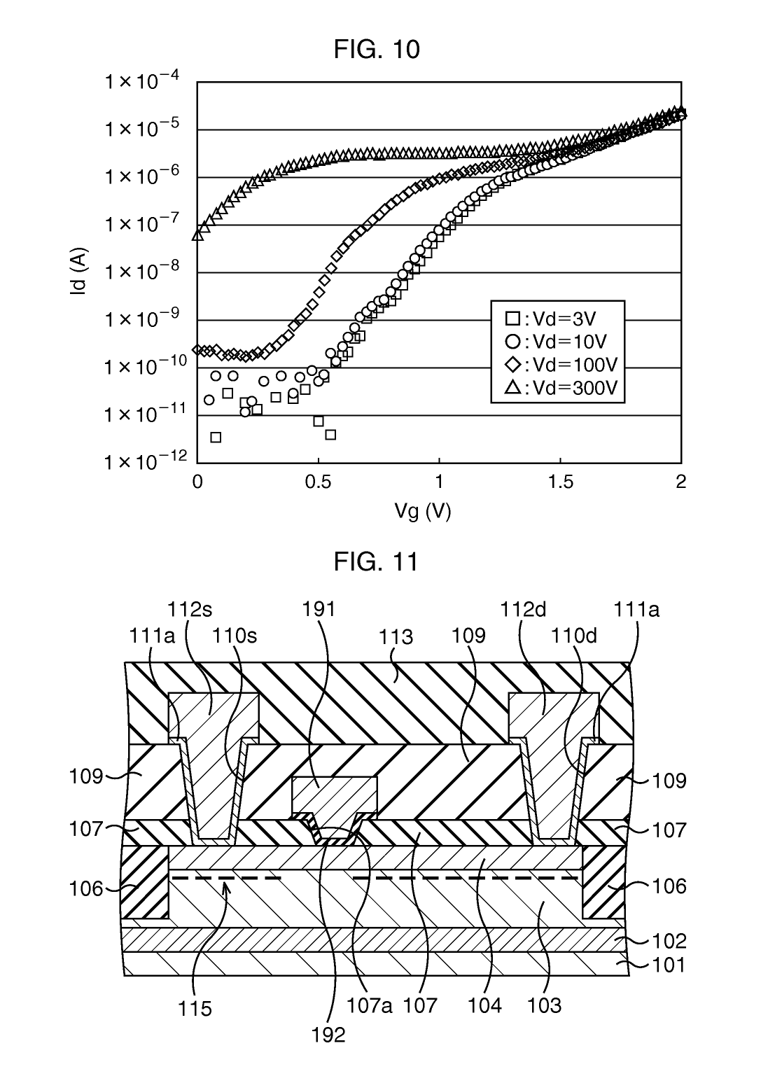

Here, the characteristics of the second embodiment will be described prior to the detailed description about the third embodiment. The result illustrated in FIG. 10 was obtained, when the relativity of the Vg-Id characteristics to the drain voltage of a GaN-based HEMT was measured, which was manufactured by the inventors following the second embodiment. A thickness of the protective film 107 was 300 nm beneath the field plate 121. As illustrated in FIG. 10, if a gate voltage (Vg) at which the drain current (Id) is 1×10⁻⁶ A is defined as a threshold voltage, the threshold voltage was about +1.3V when the drain voltage was 3V or 10V. However, the threshold voltage was about +0.3V when the drain voltage was 300V. Thus, if the drain voltage is over 10V, electric field concentration may not be eased sufficiently. In the third embodiment, electric field concentration may be eased sufficiently, even if the drain voltage is high.

Further, characteristics of a GaN-based HEMT will be described, referring to a third referential example. FIG. 11 is a view illustrating a GaN-based HEMT according to the third referential example. In the third referential example, which was manufactured by the inventors, an AlGaN layer whose Al fraction was 15%, 20% or 22% and whose thickness was 20 nm was used as the electron supply layer 104. Moreover, as illustrated in FIG. 11, the two-dimensional electron gas suppressing layer 105 was not provided, and a gate electrode 191 was formed in the opening 107a in the protective film 107 via an insulating film 192.

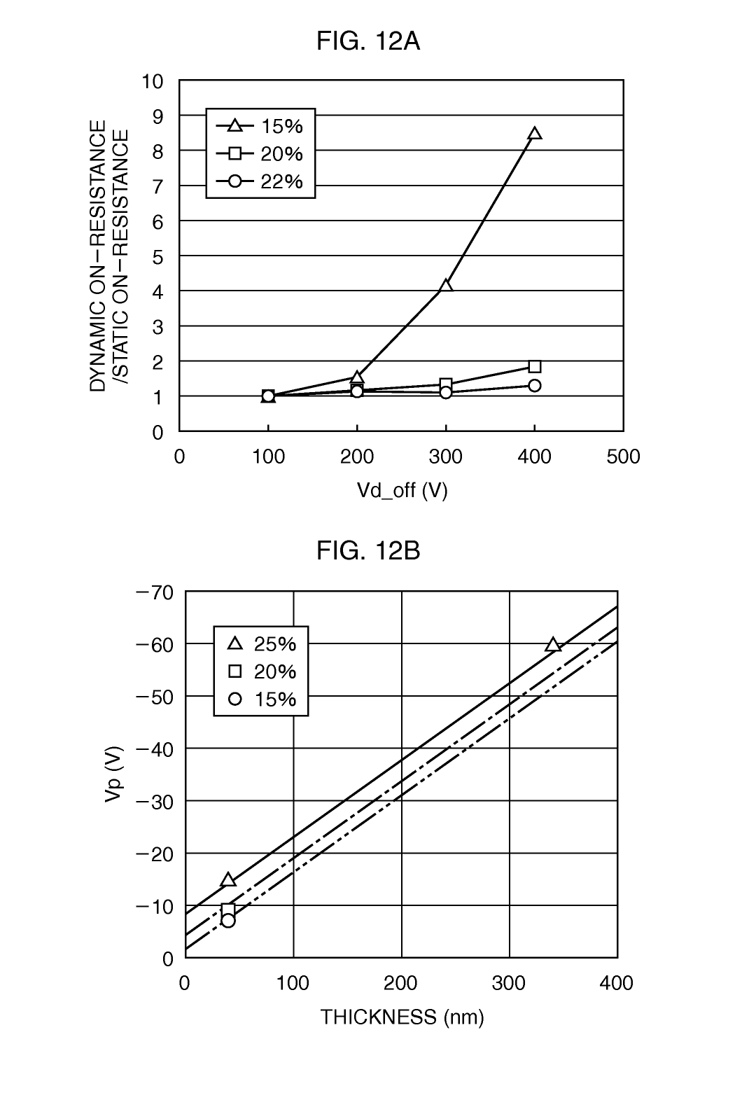

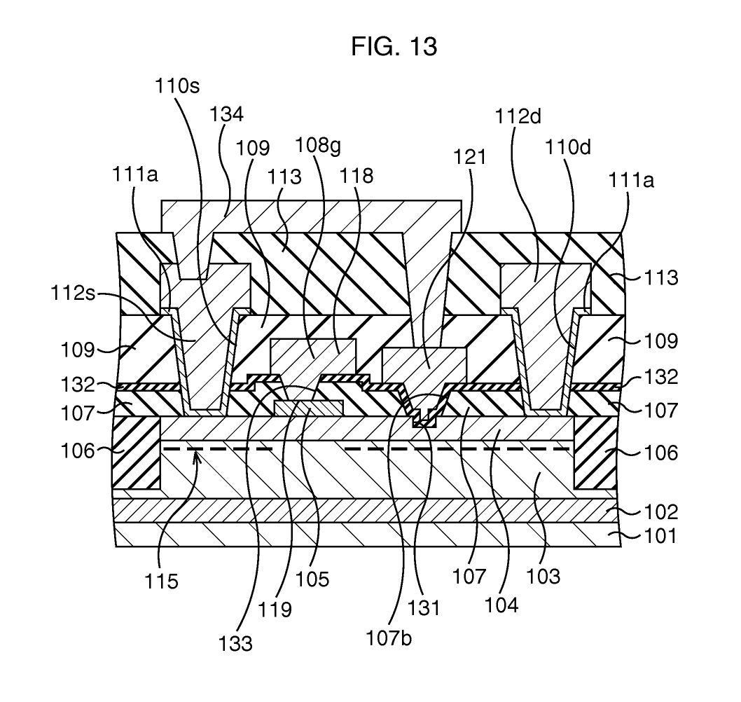

The result illustrated in FIG. 12A was obtained, when the relativity of the ratio between a dynamic on-resistance and a static on-resistance (“dynamic on-resistance”/“static on-resistance”) to the off-state drain voltage (Vg_off) of the GaN-based HEMT was measured about each of the Al fractions. It is clear that the dynamic on-resistance is higher than the static on-resistance when the drain voltage is 200V or higher from the result illustrated in FIG. 12A. Besides, it is also clear that the ratio between the dynamic on-resistance and the static on-resistance extremely depends on the Al fraction. It is thought that the Al fraction is preferably 15% or higher and more preferably 20% or higher when the drain voltage is as high as 200V. Also, the Al fraction is preferably less than 40% in order to decrease defects and increase crystallinity. Further, it is understandable that the dynamic on-resistance enormously increases more than the static on-resistance, if the Al fraction is set lower in order to increase the threshold voltage of the first referential example (FIG. 2) from the result illustrated in FIG. 12A. This trend also appears if the thickness of the AlGaN layer is set thinner in order to increase the threshold voltage.

Furthermore, the result illustrated in FIG. 12B was obtained, when the relation between a thickness of the insulating film 192 being a gate insulating film (specific permittivity: about 7 to 9) and a pinch-off voltage (Vp) was measured about each of the Al fractions. The pinch-off voltage of the third referential example is equivalent to a voltage which eases the electric field with the function of the field plate. Therefore, it is clear that the drain voltage up to about 47V may remain to be applied to the channel without being eased, when the thickness of the protective film 107 is 300 nm and the Al fraction of the electron supply layer 104 (AlGaN layer) is 20% in the second embodiment from the result illustrated in FIG. 12B. It is also clear that the thinner the protective film 107 is beneath the field plate 121, the lower the voltage applied to the channel is. However, if the whole of the protective film 107 is approximately 40 nm, the thickness between the MIS forming portion 118 and the two-dimensional electron gas suppressing layer 105 may be insufficient. Accordingly, it is preferable that the thickness of the protective film 107 is thinner at a region beneath the field plate 121 than at a region between the MIS forming portion 118 and the two-dimensional electron gas suppressing layer 105.

Further, it is thought that, if the thickness of the protective film 107 is approximately 40 nm beneath the field plate 121, the voltage applied to the channel is about 10V when the Al fraction is 20% from the result illustrated in FIG. 12B. It is preferable in view of easing electric field concentration, but a breakdown voltage may decrease since a drain voltage is applied to the protective film 107 beneath the field plate 121. The decrease of the breakdown voltage may be suppressed by forming a recess at a surface of the electron supply layer 104. Forming a recess leads to decrease of a thickness of the electron supply layer 104 there, and therefore 2DEG decreases beneath the recess. As a result, the pinch-off voltage may be suppressed, even if the thickness of the protective film 107 is not thinned up to about 40 nm beneath the field plate 121, for example even if the thickness is set to about 100 nm.

Therefore, in the third embodiment, the distance between the field plate 121 and the electron supply layer 104 is reduced compared to the second embodiment, and a recess is formed at the electron supply layer 104, based on the above described perceptions. FIG. 13 is a cross sectional view illustrating a compound semiconductor device according to the third embodiment.

In the compound semiconductor device (GaN-based HEMT) according to the third embodiment, as illustrated in FIG. 13, a recess 131 is formed at a surface of the electron supply layer 104 beneath the field plate 121, and an opening 107b (second opening) is formed in the protective film 107 so that the recess 131 is exposed through the opening 107b. An insulating film 132 (second insulating film) thinner than the protective film 107 is formed over the protective film 107. The insulating film 132 covers the side surface of the opening 107b and the inner surface of the recess 131. The field plate 121 is formed so as to go into the opening 107b and the recess 131. An opening 133 is formed in the protective film 107 and the insulating film 132 instead of the opening 107a, and the gate electrode 108g is formed over the insulating film 132 so as to be in contact with the two-dimensional electron gas suppressing layer 105 through the opening 133. The source electrode 112s and the field plate 121 are electrically connected to each other via a wiring 134. The other structure is similar to the second embodiment.

In the third embodiment, the total thickness of the protective film 107 and the insulating film 132 may be secured enough to obtain a sufficient breakdown voltage in the vicinity of the gate electrode 108g, and the field plate 121 may sufficiently function to ease the electric field concentration. These are because the distance between the field plate 121 and the electron supply layer 104 is shorter than the distance between the MIS forming portion 118 and the two-dimensional electron gas suppressing layer 105 in a thickness direction. Furthermore, higher breakdown voltage may be obtained due to the recess 131.

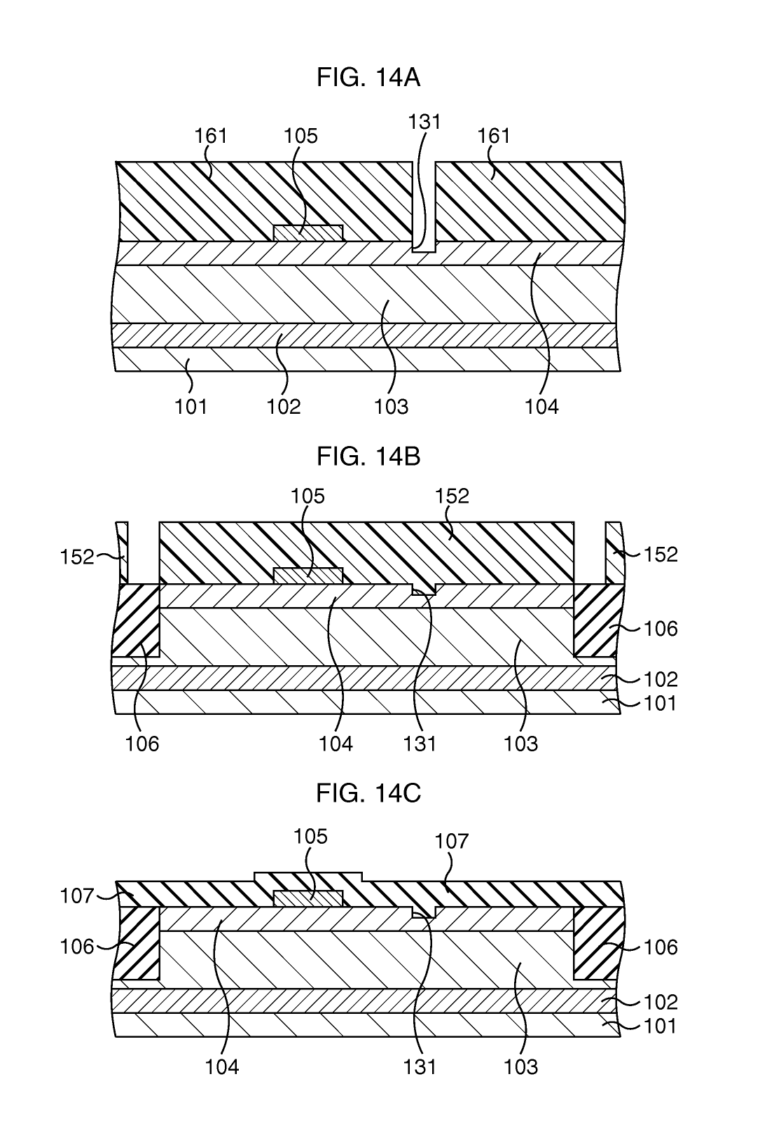

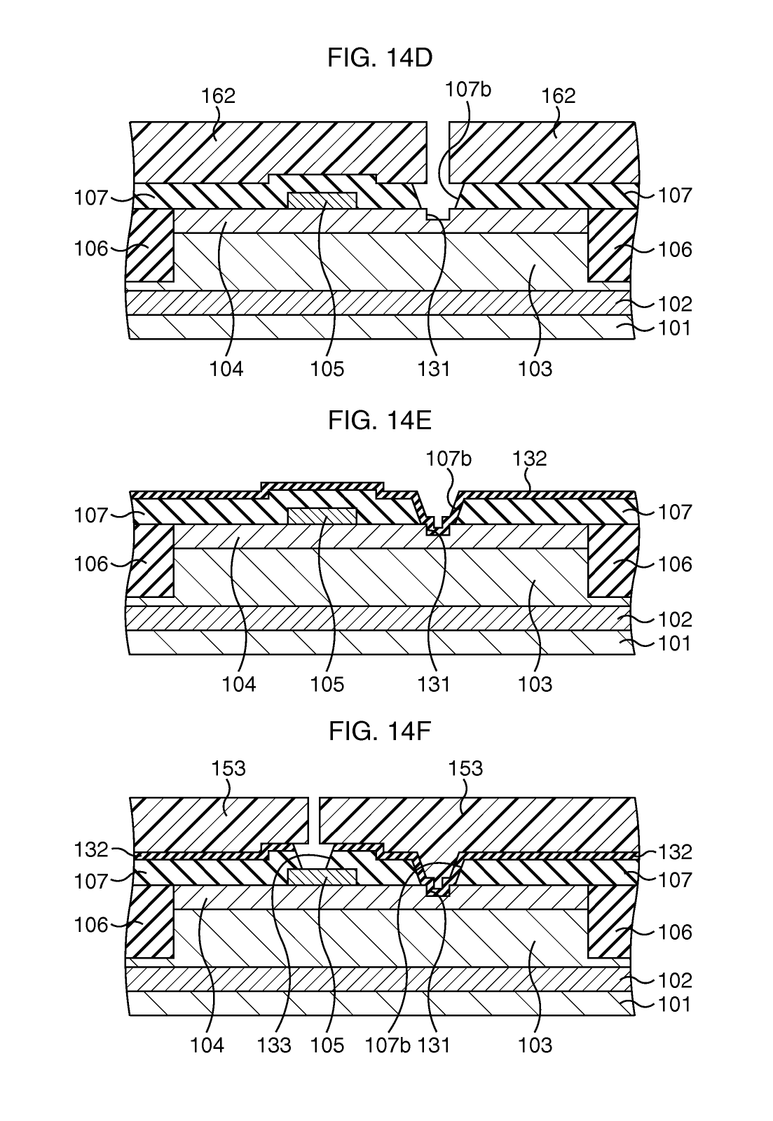

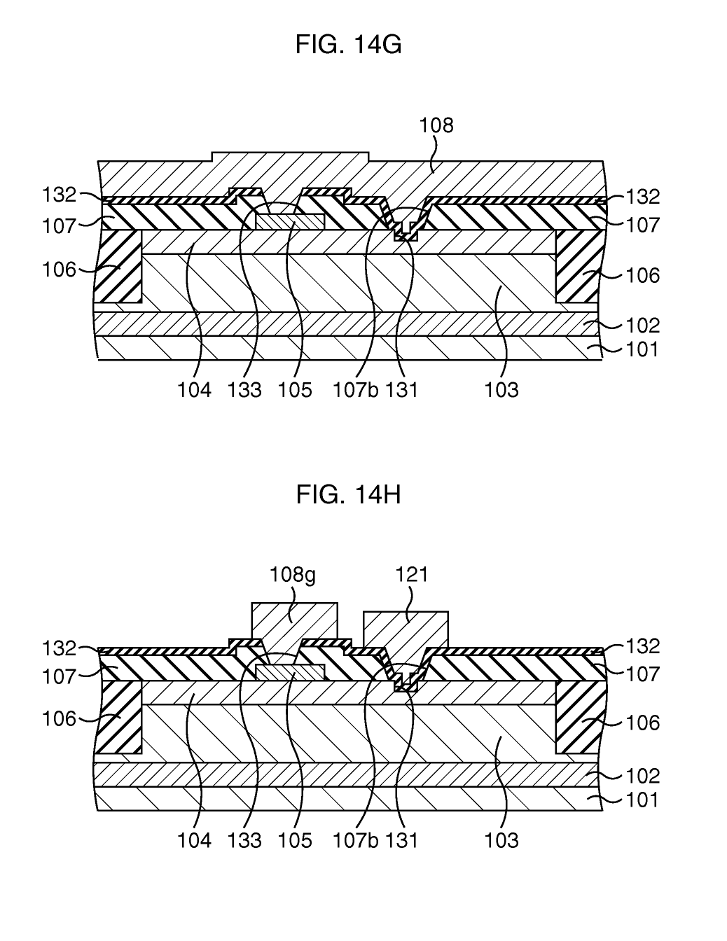

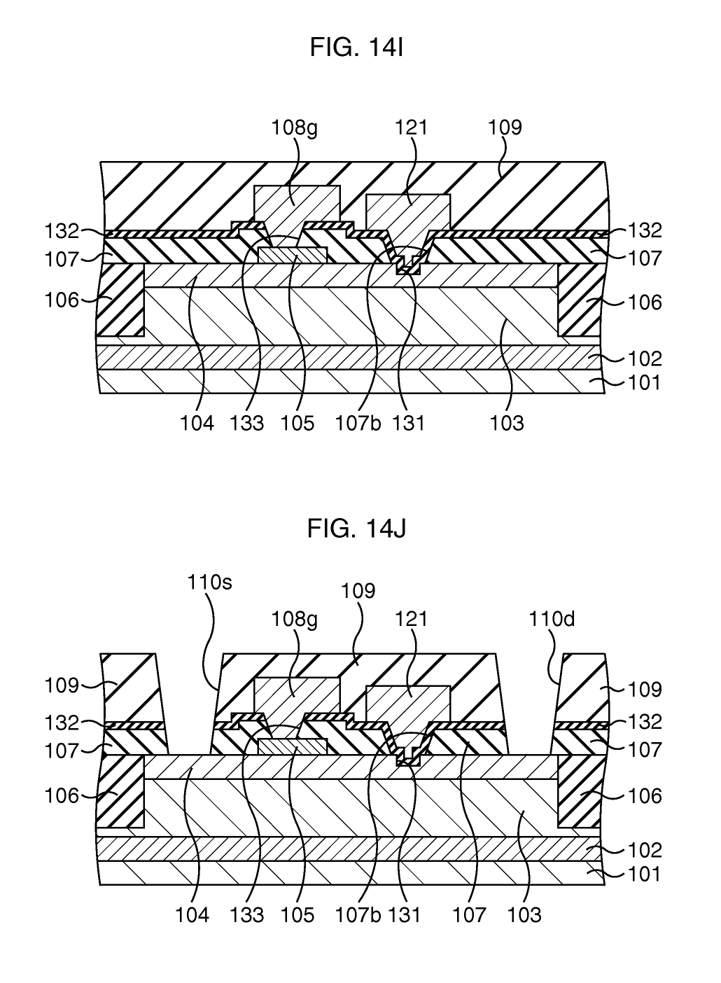

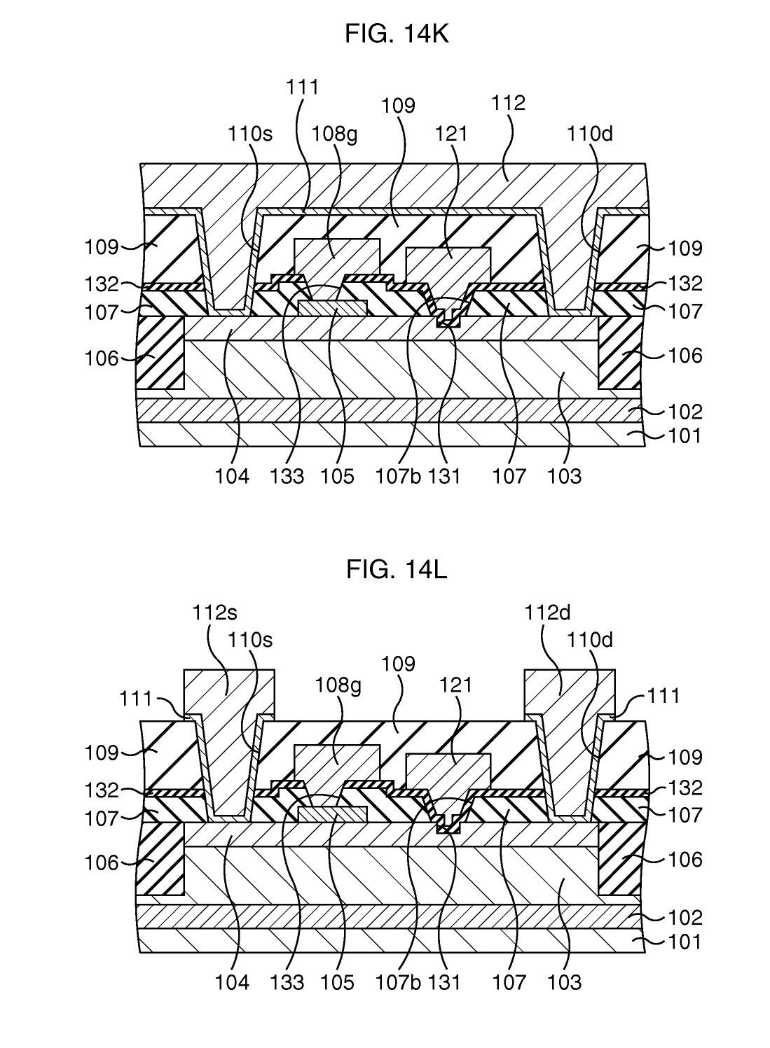

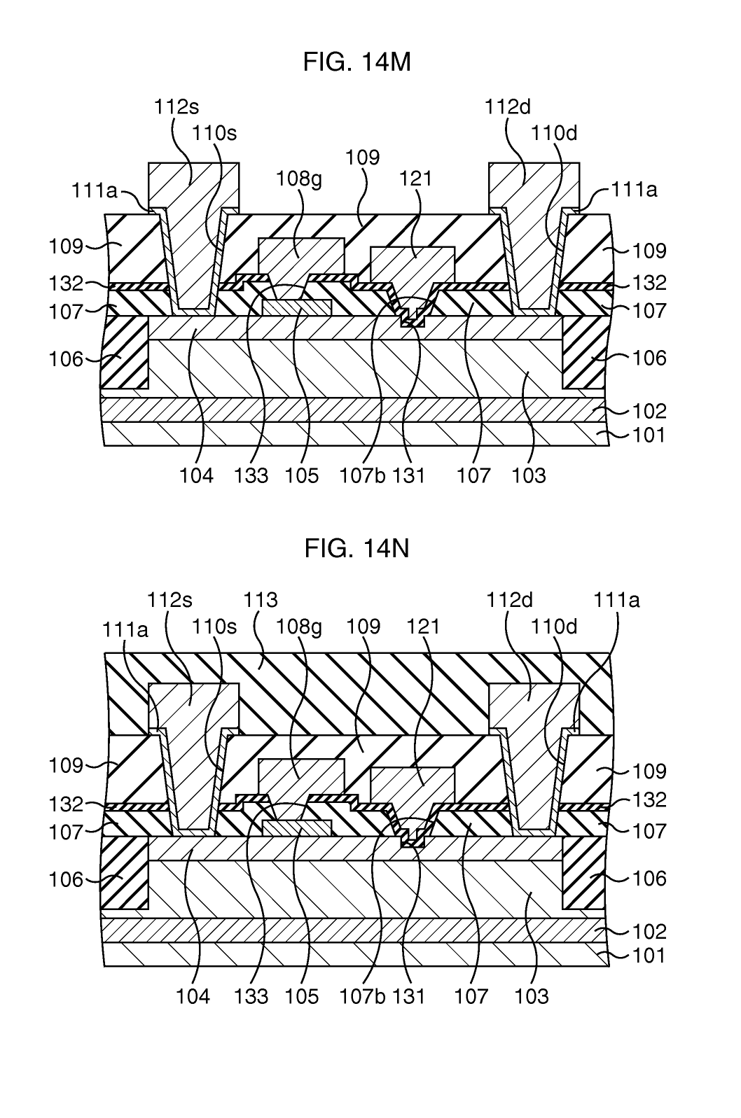

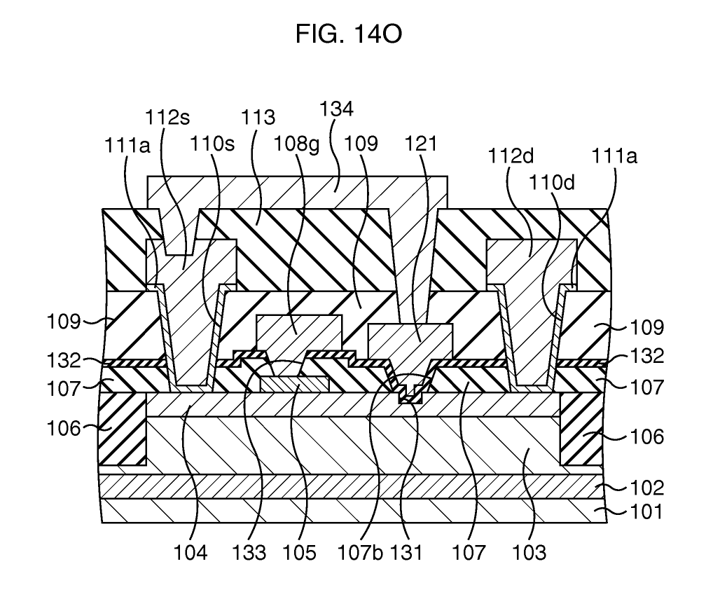

Next, a method of manufacturing the compound semiconductor device according to the third embodiment will be described. FIG. 14A to FIG. 14O are cross sectional views illustrating, in sequence, the method of manufacturing the compound semiconductor device according to the third embodiment.

First, as illustrated in FIG. 14A, processings to etching the two-dimensional electron gas suppressing layer 105 and removing the resist pattern 151 are performed similarly to the first embodiment. Then, a resist pattern 161 is formed over the electron supply layer 104 so as to expose a region in which a recess is to be formed and cover the residual region. The electron supply layer 104 is etched using the resist pattern 161 as a mask so as to form the recess 131. In the etching, dry etching is performed, for example, with a parallel flat type etching apparatus, in a chlorine gas atmosphere with a substrate temperature being 25° C. to 150° C., a pressure being 10 mT to 2 Torr, and an RF power being 50 W to 400 W. Alternatively, dry etching may be performed with an electron cyclotron resonance (ECR) etching apparatus or an inductively coupled plasma (ICP) etching apparatus, in a chlorine gas atmosphere with a substrate temperature being 25° C. to 150° C., a pressure being 1 mT to 50 mTorr, and a bias power being 5 W to 80 W.

Thereafter, as illustrated in FIG. 14B, the resist pattern 161 is removed. Subsequently, similarly to the first embodiment, the resist pattern 152 is formed over the electron supply layer 104, and ion implantation using the resist pattern 152 as a mask is performed so as to form the element isolation region 106, which defines the element region. Here, Ar ion or B-based ion is implanted, for example.

Then, as illustrated in FIG. 14C, the protective film 107 is formed similarly to the first embodiment.

Thereafter, as illustrated in FIG. 14D, a resist pattern 162 is formed over the protective film 107 so as to expose a region of the protective film 107 in which a field plate is to be formed and cover the residual region. Wet etching is performed with chemical containing hydrofluoric acid using the resist pattern 162 as a mask. As a result, the opening 107b is formed in a region in which a field plate is to be formed in the protective film 107.

Subsequently, as illustrated in FIG. 14E, the insulating film 132 is formed over the entire surface. A silicon nitride film, a silicon oxide film, an aluminum oxide film, an aluminum nitride film, a hafnium oxide film, a hafnium aluminate film, a zirconium oxide film, a hafnium silicate film, a hafnium nitride silicate film or a gallium oxide film with a thickness of approximately 10 nm to 200 nm may be formed, for example, as the insulating film 132. Alternatively, a stack of two or more kinds of the films may be formed as the insulating film 132. It is preferable that post deposition annealing (PDA) is performed at a temperature of 500° C. to 800° C. after forming the insulating film 132. By the annealing, C and H contained in the insulating film 132 may be removed.

Then, as illustrated in FIG. 14F, the resist pattern 153 is formed over the insulating film 132 so as to expose a region of the insulating film 132 and the protective film 107 in which a gate electrode is to be formed and cover the residual region. Wet etching is performed with chemical containing hydrofluoric acid using the resist pattern 153 as a mask. As a result, the opening 133 is formed in a region in which a gate electrode is to be formed in the insulating film 132 and the protective film 107.

Thereafter, as illustrated in FIG. 14G, the resist pattern 153 is removed. Subsequently, similarly to the first embodiment, the conductive film 108 to be a gate electrode is formed over the entire surface.

Subsequently, as illustrated in FIG. 14H, the conductive film 108 is patterned so as to form the gate electrode 108g and the field plate 121. As for patterning the conductive film 108, a resist pattern is formed over the conductive film 108 so as to cover regions in which the gate electrode 108g and the field plate 121 are to be formed and expose the residual region, dry etching is performed using the resist pattern as a mask, and the resist pattern is removed.

Then, as illustrated in FIG. 14I, similarly to the first embodiment, the protective film 109 is formed.

Thereafter, the opening 110s is formed in a region in which a source electrode is to be formed, and the opening 110d is formed in a region in which a drain electrode is to be formed, in the protective film 109, the insulating film 132 and the protective film 107. As for forming the opening 110s and the opening 110d, a resist pattern is formed over the protective film 109 so as to exposes regions in which the opening 110s and the opening 110d are to be formed and cover the residual region, dry etching is performed using the resist pattern as a mask, and resist pattern is removed.

Subsequently, as illustrated in FIG. 14K, similarly to the first embodiment, the conductive film 111 and the conductive film 112 are formed. Then, as illustrated in FIG. 14L, similarly to the first embodiment, the conductive film 112 and the conductive film 111 are patterned so as to form the source electrode 112s and the drain electrode 112d. Thereafter, as illustrated in FIG. 14M, similarly to the first embodiment, the annealing treatment is performed thereby to change the conductive film 111 to a conductive film 111a with a lower contact resistance. Subsequently, as illustrated in FIG. 14N, the protective film 113 is formed.

Then, as illustrated in FIG. 14O, an opening exposing the source electrode 112s is formed in the protective film 113, and an opening exposing the field plate 121 is formed in the protective film 113 and the protective film 109. The wiring 134 electrically connecting the source electrode 112s and the field plate 121 to each other through the openings is formed. It is preferable that an opening exposing the gate electrode 108g and an opening exposing the drain electrode 112d are also formed when the opening exposing the source electrode 112s and the opening exposing the field plate 121 are formed, and a wiring for a gate and a wiring for a drain are also formed when the wiring 134 is formed. These openings may be formed, for example, by etching using a resist pattern as a mask. These wirings may be formed, for example, by forming a metal film, patterning the metal film and so on.

### Fourth Embodiment

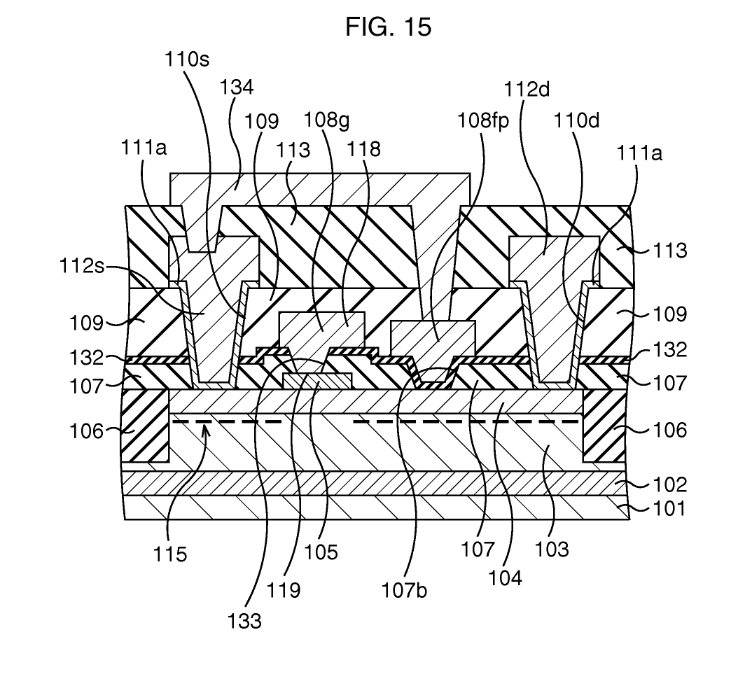

Next, a fourth embodiment will be described. FIG. 15 is a cross sectional view illustrating a structure of a compound semiconductor device according to the fourth embodiment.

In the compound semiconductor device (GaN-based HEMT) according to the fourth embodiment, as illustrated in FIG. 15, the recess 131 is not formed at the electron supply layer 104, and a surface of the electron supply layer 104 is flat beneath the field plate 121. Other structure is similar to the third embodiment.

The electric field concentration may be eased more than the second embodiment also in the fourth embodiment.

Note that the MIS forming portion and another portion of the gate electrode 108g including the contact surface 119 may be physically separated, if the same potential is applied to these portions, for example if these portions are electrically connected.

Moreover, materials of the nitride semiconductor layers such as the electron transit layer and the electron supply layer of the HEMT are not limited to GaN-based semiconductor, and AlN-based semiconductor may be used, for example. Besides, an InAlN layer may be used as the electron transit layer, and an AlN layer may be used as the electron supply layer, for example.

### Fifth Embodiment

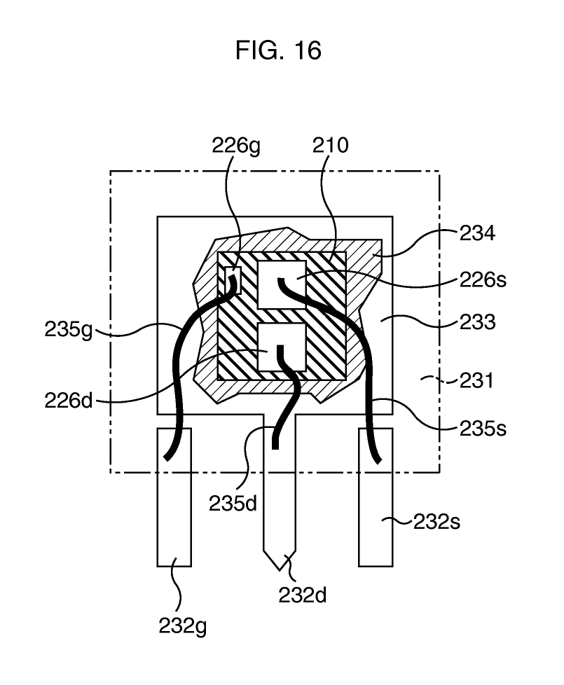

A fifth embodiment relates to a discrete package of a compound semiconductor device which includes a GaN-based HEMT. FIG. 16 is a drawing illustrating the discrete package according to the fifth embodiment.

In the fifth embodiment, as illustrated in FIG. 16, a back surface of a HEMT chip 210 of the compound semiconductor device according to any one of the first to fourth embodiments is fixed on a land (die pad) 233, using a die attaching agent 234 such as solder. One end of a wire 235d such as an Al wire is bonded to a drain pad 226d, to which the drain electrode 112d is connected, and the other end of the wire 235d is bonded to a drain lead 232d integral with the land 233. One end of a wire 235s such as an Al wire is bonded to a source pad 226s, to which the source electrode 112s is connected, and the other end of the wire 235s is bonded to a source lead 232s separated from the land 233. One end of a wire 235g such as an Al wire is bonded to a gate pad 226g, to which the gate electrode 108g is connected, and the other end of the wire 235g is bonded to a gate lead 232g separated from the land 233. The land 233, the HEMT chip 210 and so forth are packaged with a molding resin 231, so as to project outwards a portion of the gate lead 232g, a portion of the drain lead 232d, and a portion of the source lead 232s.

The discrete package may be manufactured by the procedures below, for example. First, the HEMT chip 210 is bonded to the land 233 of a lead frame, using a die attaching agent 234 such as solder. Next, with the wires 235g, 235d and 235s, the gate pad 226g is connected to the gate lead 232g of the lead frame, the drain pad 226d is connected to the drain lead 232d of the lead frame, and the source pad 226s is connected to the source lead 232s of the lead frame, respectively, by wire bonding. Then molding with the molding resin 231 is conducted by a transfer molding process. The lead frame is then cut away.

### Sixth Embodiment

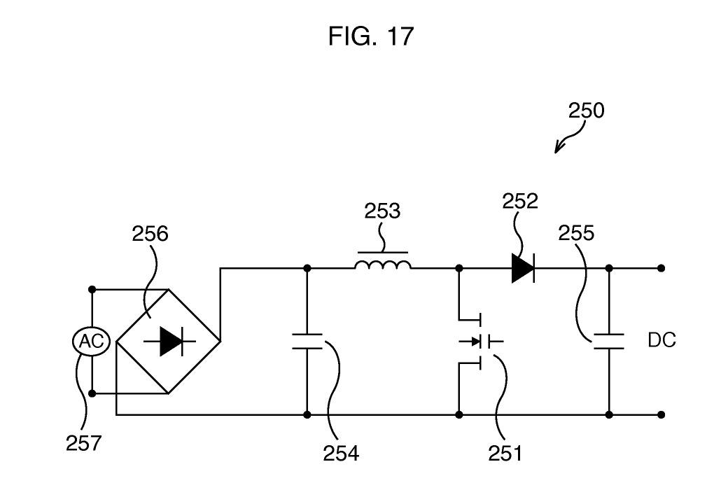

Next, a sixth embodiment will be explained. The sixth embodiment relates to a PFC (power factor correction) circuit equipped with a compound semiconductor device which includes a GaN-based HEMT. FIG. 17 is a wiring diagram illustrating the PFC circuit according to the sixth embodiment.

The PFC circuit 250 includes a switching element (transistor) 251, a diode 252, a choke coil 253, capacitors 254 and 255, a diode bridge 256, and an AC power source (AC) 257. The drain electrode of the switching element 251, the anode terminal of the diode 252, and one terminal of the choke coil 253 are connected with each other. The source electrode of the switching element 251, one terminal of the capacitor 254, and one terminal of the capacitor 255 are connected with each other. The other terminal of the capacitor 254 and the other terminal of the choke coil 253 are connected with each other. The other terminal of the capacitor 255 and the cathode terminal of the diode 252 are connected with each other. A gate driver is connected to the gate electrode of the switching element 251. The AC 257 is connected between both terminals of the capacitor 254 via the diode bridge 256. A DC power source (DC) is connected between both terminals of the capacitor 255. In the embodiment, the compound semiconductor device according to any one of the first to fourth embodiments is used as the switching element 251.

In the process of manufacturing the PFC circuit 250, for example, the switching element 251 is connected to the diode 252, the choke coil 253 and so forth with solder, for example.

### Seventh Embodiment

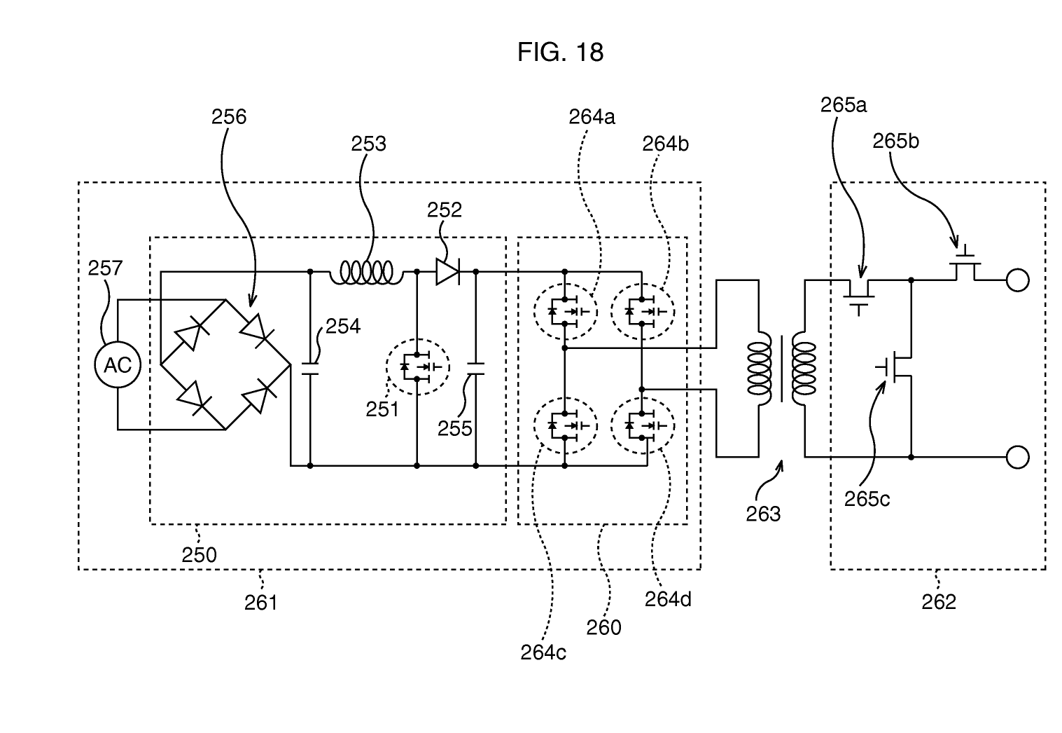

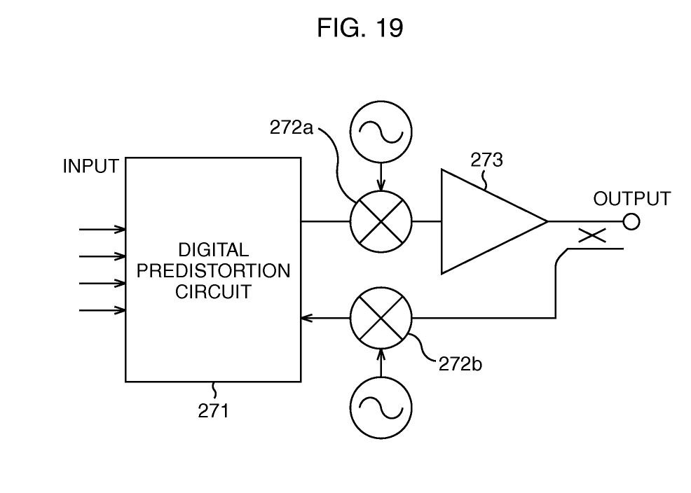

Next, a seventh embodiment will be explained. The seventh embodiment relates to a power supply apparatus equipped with a compound semiconductor device which includes a GaN-based HEMT. FIG. 18 is a wiring diagram illustrating the power supply apparatus according to the seventh embodiment.

The power supply apparatus includes a high-voltage, primary-side circuit 261, a low-voltage, secondary-side circuit 262, and a transformer 263 arranged between the primary-side circuit 261 and the secondary-side circuit 262.

The primary-side circuit 261 includes the PFC circuit 250 according to the sixth embodiment, and an inverter circuit, which may be a full-bridge inverter circuit 260, for example, connected between both terminals of the capacitor 255 in the PFC circuit 250. The full-bridge inverter circuit 260 includes a plurality of (four, in the embodiment) switching elements 264a, 264b, 264c and 264d.

The secondary-side circuit 262 includes a plurality of (three, in the embodiment) switching elements 265a, 265b and 265c.

In the embodiment, the compound semiconductor device according to any one of first to fourth embodiments is used for the switching element 251 of the PFC circuit 250, and for the switching elements 264a, 264b, 264c and 264d of the full-bridge inverter circuit 260. The PFC circuit 250 and the full-bridge inverter circuit 260 are components of the primary-side circuit 261. On the other hand, a silicon-based general MIS-FET (field effect transistor) is used for the switching elements 265a, 265b and 265c of the secondary-side circuit 262.

### Eighth Embodiment

Next, an eighth embodiment will be explained. The eighth embodiment relates to a high-frequency amplifier equipped with a compound semiconductor device which includes a GaN-based HEMT. FIG. 19 is a wiring diagram illustrating the high-frequency amplifier according to the eighth embodiment.

The high-frequency amplifier includes a digital predistortion circuit 271, mixers 272a and 272b, and a power amplifier 273.

The digital predistortion circuit 271 compensates non-linear distortion in input signals. The mixer 272a mixes the input signal having the non-linear distortion already compensated, with an AC signal. The power amplifier 273 includes the compound semiconductor device according to any one of the first to fourth embodiments, and amplifies the input signal mixed with the AC signal. In the illustrated example of the embodiment, the signal on the output side may be mixed, upon switching, with an AC signal by the mixer 272b, and may be sent back to the digital predistortion circuit 271.

According to the compound semiconductor devices and so forth described above, since a gate electrode is electrically connected to a two-dimensional electron gas suppressing layer, the normally-off operation is achieved with a high threshold voltage.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A compound semiconductor device comprising:
an electron transit layer;
an electron supply layer formed over the electron transit layer;
a two-dimensional electron gas suppressing layer formed over the electron supply layer;
an insulating film formed over the two-dimensional electron gas suppressing layer and the electron transit layer; and
a gate electrode formed over the insulating film,
wherein the gate electrode is electrically connected with the two-dimensional electron gas suppressing layer.

2. The compound semiconductor device according to claim 1, further comprising a source electrode and a drain electrode formed over the electron supply layer, the source electrode and the drain electrode sandwiching the two-dimensional electron gas suppressing layer in planar view,
wherein the gate electrode is electrically connected with the two-dimensional electron gas suppressing layer at a contact surface on the source electrode side of a portion located above the insulating film.

3. The compound semiconductor device according to claim 1, wherein
the electron transit layer is a GaN layer,
the electron supply layer is AlGaN layer, and
the two-dimensional electron gas suppressing layer is a p-type GaN layer.

4. The compound semiconductor device according to claim 3, wherein
a thickness of the AlGaN layer is 5 nm or more and 40 nm or less, and
an Al fraction of the AlGaN layer is 15% or more and less than 40%.

5. The compound semiconductor device according to claim 2, further comprising a field plate located between the gate electrode and the drain electrode, and electrically connected with the source electrode.

6. The compound semiconductor device according to claim 5, wherein a distance between the field plate and the electron supply layer in a thickness direction is shorter than a distance between the portion located above the insulating film and the two-dimensional electron gas suppressing layer in the thickness direction.

7. The compound semiconductor device according to claim 5, wherein a recess is formed at a surface of the electron supply layer beneath the field plate.

8. The compound semiconductor device according to claim 2, wherein the gate electrode covers whole of the two-dimensional electron gas suppressing layer between the source electrode and the drain electrode.

9. The compound semiconductor device according to claim 1, wherein a thickness of the insulating film is 20 nm or more and 500 nm or less.

10. A power supply apparatus comprising
a compound semiconductor device, which comprises:
an electron transit layer;
an electron supply layer formed over the electron transit layer;
a two-dimensional electron gas suppressing layer formed over the electron supply layer;
an insulating film formed over the two-dimensional electron gas suppressing layer and the electron transit layer; and
a gate electrode formed over the insulating film,
wherein the gate electrode is electrically connected with the two-dimensional electron gas suppressing layer.

11. An amplifier comprising
a compound semiconductor device, which comprises:
an electron transit layer;
an electron supply layer formed over the electron transit layer;
a two-dimensional electron gas suppressing layer formed over the electron supply layer;
an insulating film formed over the two-dimensional electron gas suppressing layer and the electron transit layer; and
a gate electrode formed over the insulating film,
wherein the gate electrode is electrically connected with the two-dimensional electron gas suppressing layer.

12. A method of manufacturing a compound semiconductor device, comprising:
forming an electron supply layer over an electron transit layer;
forming a two-dimensional electron gas suppressing layer over the electron supply layer;
forming an insulating film over the two-dimensional electron gas suppressing layer and the electron transit layer; and
forming a gate electrode over the insulating film,
wherein the gate electrode is electrically connected with the two-dimensional electron gas suppressing layer.

13. The method of manufacturing a compound semiconductor device according to claim 12, further comprising forming a source electrode and a drain electrode over the electron supply layer, the source electrode and the drain electrode sandwiching the two-dimensional electron gas suppressing layer in planar view,
wherein the gate electrode is electrically connected with the two-dimensional electron gas suppressing layer on the source electrode side of a portion of the gate electrode, the portion being located above the insulating film.

14. The method of manufacturing a compound semiconductor device according to claim 13, wherein the forming the gate electrode comprises:
forming an opening in the insulating film through which a part of the two-dimensional electron gas suppressing layer is exposed;
forming a conductive film in contact with the two-dimensional electron gas suppressing layer through the opening; and
patterning the conductive film so that the portion being located above the insulating film is on the drain electrode side of a surface at which the conductive film is in contact with the two-dimensional electron gas suppressing layer.

15. The method of manufacturing a compound semiconductor device according to claim 12, wherein
the electron transit layer is a GaN layer,
the electron supply layer is AlGaN layer, and
the two-dimensional electron gas suppressing layer is a p-type GaN layer.

16. The method of manufacturing a compound semiconductor device according to claim 15, wherein a thickness of the AlGaN layer is 5 nm or more and 40 nm or less, and
an Al fraction of the AlGaN layer is 15% or more and less than 40%.

17. The method of manufacturing a compound semiconductor device according to claim 13, further comprising forming a field plate between the gate electrode and the drain electrode in planar view, the field plate being electrically connected with the source electrode.

18. The method of manufacturing a compound semiconductor device according to claim 17, wherein a distance between the field plate and the electron supply layer in a thickness direction is shorter than a distance between the portion and the two-dimensional electron gas suppressing layer in the thickness direction.

19. The method of manufacturing a compound semiconductor device according to claim 18, further comprising, before the forming the field plate:
forming a second opening in the insulating film; and
forming a second insulating film thinner than the insulating film in the second opening,
wherein the field plate is formed over the second insulating film.

20. The method of manufacturing a compound semiconductor device according to claim 19, further comprising, between the forming the second opening and the forming the second insulating film, forming a recess at a surface of the electron supply layer which is exposed through the second opening.

21. The method of manufacturing a compound semiconductor device according to claim 13, wherein the gate electrode is formed so as to cover whole of the two-dimensional electron gas suppressing layer between the source electrode and the drain electrode.

22. The method of manufacturing a compound semiconductor device according to claim 12, wherein a thickness of the insulating film is 20 nm or more and 500 nm or less.
